(19) United States
(12) Patent Application Publication
(10) Pub. No.: US 2023/0268461 A1
(43) Pub. Date: Aug. 24, 2023

(54) OPTOELECTRONIC DEVICE WITH SUB-WAVELENGTH ANTIREFLECTIVE STRUCTURE, ASSOCIATED SCREEN AND MANUFACTURING METHOD

(71) Applicant: COMMISSARIAT À L'ENERGIE ATOMIQUE ET AUX ENERGIES ALTERNATIVES, Paris (FR)

(72) Inventors: Amade NDIAYE, GRENOBLE CEDEX 09 (FR); Badhise BEN BAKIR, GRENOBLE CEDEX 09 (FR)

(21) Appl. No.: 18/171,864

(22) Filed: Feb. 21, 2023

(30) Foreign Application Priority Data
Feb. 21, 2022 (FR) 2201498

(51) Int. Cl. H01L 33/20; H01L 33/00

(52) U.S. Cl. CPC H01L 33/20; H01L 33/0062; H01L 33/30

(57) ABSTRACT

An optoelectronic device includes an emissive structure, at least a part of which is formed of one or more semiconductor materials, configured to produce a luminous radiation when it has an electric current flowing therethrough, the luminous radiation being produced within the emissive structure and having an average wavelength λ, the emissive structure having an average optical index n and being delimited by an outlet surface, through which at least a part of the luminous radiation exits, the device further including an antireflective structure includes a sub-wavelength periodic grating which includes hollow parts and protruding parts forming a periodic structure with a pitch lower than λ/[2.n].

### CROSS-REFERENCE TO RELATED APPLICATIONS

This application claims priority to French Patent Application No. 2201498, filed Feb. 21, 2022, the entire content of which is incorporated herein by reference in its entirety.

### FIELD

The technical field is that of microelectronics, more particularly that of optoelectronic devices for emitting light, such as light-emitting diodes, for example.

### BACKGROUND

Luminous sources based on semiconductors, such as light-emitting diodes or laser diodes, are more and more used and have been growing steadily for many years.

Recently, important advances have been made in the field of microLEDs and microLED screens, as well as in the field of larger (and more powerful) LEDs for lighting.

However, for the so-called “surface-emitting” emissive structures, such as LEDs (Light-Emitting Diodes) or VCSELs (Vertical-Cavity Surface-Emitting Lasers), an important issue is to limit retroreflections at the outlet surface of the radiation.

Indeed, semiconductor material(s) forming these emissive structures have optical indices that are generally much higher than the optical index of the medium into which the radiation exits, for example air (or a transparent filling material, such as silicon oxide).

Without special precautions, this large difference in indices causes significant reflection at the outlet surface of the emissive structure, for the radiation produced, even at normal incidence, thus reducing the amount of light finally delivered by the structure.

In order to reduce the reflection coefficient, the emissive structure has an antireflective layer at this outlet surface, formed by a homogeneous material of index n_{AR}, which can be deposited on this surface. A maximum transmission is obtained when the antireflective layer has a thickness equal to λ/(4.n_{AR}), and when the index n_{AR} is equal to \sqrt{n. nₒᵤₜ}, n being the average optical index of the emissive structure, nₒᵤₜ being the index of the medium in which the luminous radiation exits, and λ being the average wavelength of the emitted radiation (wavelength in vacuum).

In practice, among the different possible materials (materials which have to be transparent and adapted to thin film deposition), the one whose index is closest to the optimal value \sqrt{n. nₒᵤₜ} is selected. But in general, the index of this material is not quite equal to this optimal value, such that a more or less important residual reflection 10 persists, at the outlet surface.

Within this context, the article “Improved Device Performance of AlGaInP-Based Vertical Light-Emitting Diodes with Low-n ATO Antireflective Coating Layer”, by Hee Kwan Lee et al, Microelectronic Engineering, 104 (Apr. 1, 2013), pp 29-32 describes an LED whose outlet face is provided with an antireflective layer formed by a thin, porous layer of ATO (antimony tin oxide).

This layer, 90 nm thick, is formed of tilted ATO nanocolumns, each having a diameter between about 10 and 30 nm, separated by air, and arranged in a disordered manner on the outlet face of the LED (see image 1b in the article in question). This layer is obtained by performing a vapor deposition (by RF magnetron sputtering), with a very tilted flux relative to the surface of the emissive structure. For certain conditions of pressure and tilt, a self-organisation of the ATO deposited, which self-organises in columnar form, is observed.

The emission wavelength of the LED, λ, is about 635 nm, and the index n of the upper layer of the LED, made of GaP, is about 3.3 at this wavelength. The typical dimensions of the nanostructures of the ATO layer are thus lower, and even much lower than λ/(2n), so that the layer can be considered optically equivalent (at least as a first approximation) to a homogeneous layer, whose effective, uniform index has an intermediate value between the air index and the ATO index.

This layer makes it possible to increase by about 20% the luminous power actually delivered by the LED, compared to an LED without any antireflective layer (for a same electric current flowing through the LED).

The effective index n_{eff} of this ATO layer can be adjusted, to some extent, by varying the flux tilt (which modifies porosity of the ATO layer), during the deposition of the layer. This allows this index to be adjusted to approach the optimal value \sqrt{n. nₐᵢᵣ}.

However, this type of antireflective layer has several limitations.

First, the radiation finally emitted into the air is distributed over a very wide emission angle (total width at half height of about 120 degrees; see FIG. 4 of the above-mentioned article by Hee Kwan Lee). Besides, the angular width of the emission cone is substantially the same with this antireflective layer as without. But, for certain applications, especially for high-resolution display (especially for augmented reality and virtual reality), it is desirable to concentrate the emission in a relatively closed cone, having for example an aperture of more or less 30 degrees, or even of more or less 15 degrees (that is: 15 degrees on each side, namely a total aperture of 30 degrees), because the light located outside such an emission cone will not reach the eye of the observer, or might create ghost images.

Moreover, the method for manufacturing this layer is based on manufacturing techniques different from those generally utilised for the planar integration of structures of micron dimensions, and not very adapted to such a planar integration (especially because of the need to strongly tilt the sample).

On the other hand, this type of manufacture, based on self-organisation of the deposited material, allows only a part of the characteristics of the nanostructured layer to be controlled, in this instance its thickness (via a control of the deposition time), and, to a lesser extent, its porosity (via a control of the flux tilt). But, for such a layer, neither the shape, nor the dimensions (at least not independently of the porosity), nor the type of distribution of these columnar nanostructures can be controlled.

Finally, the structure of this layer is disordered, random. For large LEDs, such as that described in the above-mentioned article by Hee Kwan Lee (LED having an outlet face of 1 mm²), the characteristics of the antireflective layer are well defined, and reproducible, as they correspond to an average over a very large number of nanocolumns. On the other hand, for microLEDs, whose emission surface can be as small as 5 square microns, for example (and sometimes even less), the characteristics of such an antireflective layer can vary substantially, uncontrollably, from one microLED to another. Indeed, the number of nanocolumns present on the face of the microLED, or their diameter, can fluctuate substantially from one microLED to another, as the averaging (smoothing) effect mentioned above is much less important than with a large LED. This disparity in the characteristics of the layer, from one micro-LED to another, can then result in an inhomogeneity of brightness and thus a kind of undesirable display noise, for a microLED screen.

### SUMMARY

To address at least partly the limitations of prior art, an aspect of the present technology then relates to an optoelectronic device comprising:
an emissive structure:
   at least a part of which is formed of one or more semiconductor materials,
   configured to produce a luminous radiation when it is has an electric current flowing therethrough, said luminous radiation being produced within the emissive structure and having an average wavelength λ,
   the emissive structure having an average optical index n and being delimited by an outlet surface, through which at least a part of said luminous radiation exits, and
an antireflective structure, located at the outlet surface,
wherein the antireflective structure comprises a sub-wavelength periodic grating which includes hollow parts and protruding parts forming a regular periodic structure with a pitch (a) lower than λ/[2.n].

The inventors found that an antireflective layer with a regular, periodic, sub-wavelength (nanometric) structuration allowed the angular aperture of the emission cone (final emission cone, in air or in the external medium) to be modified, compared to an emissive structure without any antireflective layer, in contrast to the disordered structure in the above-mentioned article by Hee Kwan Lee (which does not modify this angular aperture). Numerical simulation results, set forth below in the description of the figures, illustrate this effect, in this instance in the case of a reduction of the angular aperture of the emission cone. The emission is then concentrated in a more closed emission cone, which is interesting for various types of applications.

It will be noted that the grating which forms this antireflective structure is not a diffractive grating. Indeed, its pitch a, that is, its spatial period, is lower than λ/(2n). Its spatial frequency spectrum is therefore entirely located above the limit cut-off frequency (2n)/λ, beyond which there are no longer diffractive effects (or resonance effects). This grating does not especially give rise to diffraction effects in the far field, and its operation is quite different from a diffractive grating. It will be noted that, for this grating, the pitch a is much lower than λ/(2n), and not simply lower than λ or even λ/2 (it is therefore quite different, among others, from a diffractive grating whose pitch is lower than λ but greater than λ/[2n]—which, in this instance, is a diffractive grating, but for which only the 0 order is transmitted, at normal incidence) The effect of the sub-wavelength grating in question should thus be analysed rather in terms of the average effective medium, as if the antireflective structure were formed of a homogeneous material. The term “refractive grating” (and not “diffractive grating”) is besides sometimes utilised to refer to such a grating in this technical field.

The fact that such a grating modifies directivity of the emitted radiation, while its operation rather has to be analysed in terms of effective homogeneous medium, is therefore surprising at first sight. One possible explanation for this effect (the details of which are probably complex and occur on a small scale) is that the effective medium in question has different properties depending on whether it is viewed at normal incidence or at non-zero incidence, which could explain the directivity modification in question.

Moreover, utilising thus a regular sub-length grating, typically made by etching, rather than a disordered nano-textured structure, allows a good reproducibility, from one optoelectronic device to another (especially in terms of luminous efficiency and directivity), particularly when the micron-sized device is of very small size.

This type of regular sub-wavelength grating can be made directly by lithography and then etching of a free upper face of the emissive structure, without any feed of external material. Indeed, for the effective optical index of the grating (that is:

for the index of the fictitious, effective, homogeneous layer representing the grating), a value is then naturally obtained which is comprised between the average optical index of the emissive structure, and the optical index of the medium in which the radiation exits. The antireflective structure thus obtained is then made without any feed of external material and is thus very stable (especially when the emissive structure is based on GaN or AlGaInP), especially compared with an antireflective layer based on organic materials, which have limited lifespan, in particular when it is about high luminance applications.

More generally, such manufacture by lithography and etching (although demanding, because of the reduced dimensions to be achieved) is conveniently integrated in the flow of manufacturing steps of a device, in particular a micron-sized device, obtained by planar techniques.

Furthermore, it allows independent control of the different characteristics of the grating. Not only its thickness and filling factor can be adjusted, but also the pitch of the grating, its mesh type, the shape of the patterns, the one- or two-dimensional character of the grating, or even the orientation of the grooves (to be adapted to the radiation polarisation), in the case of a one-dimensional grating.

In addition to the above-mentioned characteristics, the optoelectronic device just set forth may have one or more of the following optional characteristics, considered individually or according to any technically contemplatable combination:
the area occupied by the outlet surface of the emissive structure is lower than 50 μm² or even lower than 5 μm²;
the emissive structure includes a superficial upper layer, formed of a semiconductor material, and the protruding parts of said grating, formed of the same semiconductor material as said superficial upper layer, are as one piece with the upper layer of the emissive structure;
the protruding parts of the grating are formed of a material having an optical index nₚ, a medium of optical index nₒᵤₜ extends above the grating, opposite to the emissive structure, a medium of index nᵣ fills the hollow parts of the grating;
a filling factor FF of the grating, equal to the fraction of the volume of the grating occupied by its hollow parts, is equal to the filling factor FF_{TE} given by the following formula F1: \sqrt{FF_{TE}.nᵣ²+(1−FF_{TE}).nₚ²}=\sqrt{n. nₒᵤₜ} (F1);
the grating is one-dimensional, the hollow parts being rectilinear grooves parallel to each other, and wherein said radiation has a substantially rectilinear polarisation, and parallel to said grooves;
the grating is a two-dimensional grating including a pattern periodically repeated along a first direction, and also periodically repeated along a second direction different from the first direction;
the grating is one-dimensional, the hollow parts being rectilinear grooves parallel to each other, and said radiation has a substantially rectilinear polarisation perpendicular to said grooves, and a filling factor FF of the grating, equal to the fraction of the volume of the grating occupied by its hollow parts, is equal to the filling factor FF_{TM} given by the following formula F2: {square root over ((FF_{TM}.nᵣ⁻²+(1−FF_{TM}).nₚ⁻²)⁻¹)}=\sqrt{n. nₒᵤₜ} (F2);
the grating has a depth D, along a direction perpendicular to the outlet surface, the depth D being equal to λ/(4\sqrt{n. nₒᵤₜ}), nₒᵤₜ being the optical index of the medium which extends above the grating, opposite to the emissive structure;
the device is a light-emitting diode, and the emissive structure comprises:
   a lower layer, formed at least in part of a doped semiconductor,
   an upper layer, formed at least in part of a doped semiconductor, the lower and upper layers having opposite type doping, and
   an emissive part, which extends between the lower layer and the upper layer and which is capable of emitting said luminous radiation when it has an electric current flowing therethrough.

The present technology also relates to a display screen comprising an array of optoelectronic devices as described above.

An aspect of the present technology also relates to a method for manufacturing such an optoelectronic device, comprising:
a step of making an emissive structure, at least a part of which is formed of one or more semiconductor materials, configured to produce a luminous radiation when it is has an electric current flowing therethrough, said luminous radiation being produced within the emissive structure and having an average wavelength λ, the emissive structure having an average optical index n and being delimited by an outlet surface, through which at least a part of said luminous radiation exits, and
a step of making an antireflective structure, located at the outlet surface,
wherein the step of making the antireflective structure comprises a step of making a sub-wavelength periodic grating which includes hollow parts and protruding parts forming a regular periodic structure with a pitch lower than λ/[2.n].

In this method, the emissive structure can have, at the end of the step of making this structure, a free upper face, and the grating can be made by electronic lithography and then etching of said upper face.

The optional characteristics, set forth above in terms of device, can also be applied to the method just described.

The present technology and its various applications will be better understood upon reading the following description and examining the accompanying figures.

### BRIEF DESCRIPTION OF THE FIGURES

The figures are set forth by way of indicating and in no way limiting purposes.

FIG. 1 schematically represents an optoelectronic device according to the present technology, seen from the side.

FIG. 2 is a schematic representation of the device of FIG. 1, in which an emissive structure of the device is represented, in a simplified manner, by a homogeneous medium.

FIG. 3 corresponds to a simplified modelling of the device of FIG. 1, in which a sub-wavelength grating-based antireflective structure of the device is represented by an effective, homogeneous antireflective layer.

FIG. 4 schematically represents the device of FIG. 1, seen from above.

FIG. 5 represents the change over time of a transmission coefficient of the antireflective structure of the device of FIG. 1, as a function of an angle of incidence on this structure.

FIG. 6, FIG. 7 and FIG. 8 each show the emission efficiency of the device, for a collection angle of more or less 90° (90° on each side, that is, the entire half space), more or less 30° and more or less 15° respectively, as a function of the depth of the grating patterns.

FIG. 9 represents the emission efficiency of the device, as a function of the collection angle.

FIG. 10 shows an alternative of the device of FIG. 1, seen from above.

FIG. 11 shows another alternative of the device of FIG. 1, seen from above.

FIG. 12 schematically represents the steps of a method for manufacturing the device of FIG. 1.

### DETAILED DESCRIPTION

As mentioned above, the present technology especially relates to an optoelectronic device, 1; 1′; 1″, for example of the LED- or VCSEL-type, comprising a surface emitting emissive structure, as well as an antireflective structure promoting the exit of the radiation produced in the emissive structure, based on a non-diffractive sub-wavelength periodic grating.

In the following, the emissive structure itself is first described, then this particular antireflective structure. Numerical simulation results illustrating the performance that can be obtained with this arrangement are then set forth.

The optoelectronic device, 1; 1′; 1″ is a device of semiconductor(s): at least a part of its emissive structure 2 is formed of one or more semiconductor materials. This emissive structure 2 is configured to produce a luminous radiation when it is has an electric current flowing therethrough. This luminous radiation is produced within the emissive structure, internally, in the volume thereof. The emissive structure 2 is delimited at the upper part by an outlet surface 4. At least a part of the radiation produced exits the emissive structure 2 through this outlet surface 4, and then propagates into an outlet medium, 5, which extends above the emissive structure. The outlet surface 4 is the free surface of the emissive structure 2, here in contact with the outlet medium 5 (it is then a somewhat serrated surface, here, due to the grating structure of this interface). In practice, the optical index nₒᵤₜ of the outlet medium (for example air, or a transparent filling material of index lower than n, which could be silicon oxide SiO₂, silicon nitride or alumina) is generally significantly smaller than the average optical index n of the emissive structure 2, based on semiconductor(s).

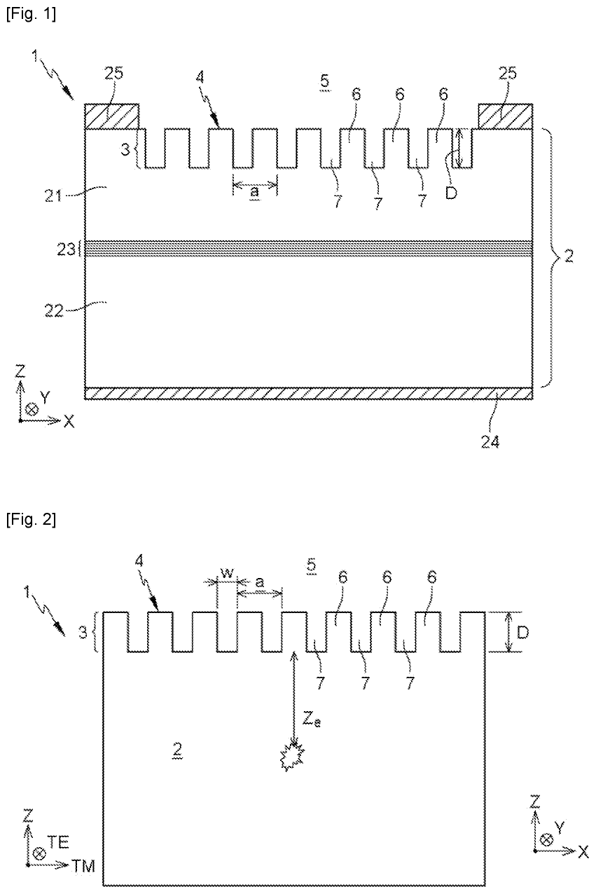

The emissive structure 2 can, as here, have a planar structure, the emissive structure then being formed by a stack of layers 21, 22, 23 which extend in parallel to each other. In practice, these layers extend in parallel to a substrate, which serves as a support for the optoelectronic device. The outlet surface 4 is then generally parallel to these layers 21, 22, 23 (that is, the average plane defined by the outlet surface 4 is parallel to the layers, for example parallel to within 10 degrees, or better). In FIGS. 1 to 4, 10, and 11, axes X, Y, and Z orthogonal in twos have been represented. The plane (X, Y) is parallel to the plane of the layers, while the direction perpendicular to the outlet surface 4 (that is: the direction perpendicular to the average plane defined by this surface) is marked by the axis Z.

The emissive structure 2 may comprise (as in the case of FIG. 1, for example):
a lower layer, 22, formed at least in part of a doped semiconductor,
an upper layer 21, formed at least in part of a doped semiconductor, the lower and upper layers 22, 21 having opposite type doping, and
an emissive part 23, which extends between the lower layer 22 and the upper layer 21 and which is capable of emitting said luminous radiation when it has an electric current flowing therethrough.

In the embodiment represented, the emissive part 23 comprises a stack of one or more planar quantum wells. Alternatively, however, the emissive part could be of a different type; it could, for example, be a simple junction between the upper and lower layers, of opposite doping (junction without any interstitial material, for example).

By “planar quantum well”, it is meant here a structure comprising a thin central layer (thickness in the order of ten nanometres), formed of a first semiconductor material, as well as two barrier layers which enclose the central layer, formed of another semiconductor material which has a wider band gap than the band gap of the first material. The thin central layer thus forms a potential well for electrons and/or holes. For example, for a red emission, the central layer and the barrier layers can be made of Aluminium-Indium-Gallium Phosphide AlInGaP and of Indium-Gallium Phosphide InGaP. More generally, when it is desired to obtain an emission in the visible range, the active layer can be made of III-V semiconductor materials, that is, comprising an element of column V of the periodic table of elements (N, As, P) associated with one or more elements of column III of the periodic table of elements (Ga, Al, In).

The lower 22 and upper 21 layers may each be as one piece. For example, when the active layer is formed of AlInGaP/InGaP wells, the lower and upper layers can each be made as a one-piece InGaP layer, one N-type doped and the other P-type doped. The lower 22 and upper 21 layers can also each be formed as a stack of several sublayers. And it can be provided that only some of these sub-layers are doped.

A conductive (for example metal) lower electrode 24 is in contact with a lower face of the lower layer 22. One or more upper, conductive (for example, metal) electrodes 25 are in contact with an upper surface of the upper layer 21. As represented in FIG. 1, the upper electrode(s) 5 occupy only a part of the upper surface of this layer (upper surface which corresponds to the outlet surface 4 mentioned above), to let the luminous radiation produced exit (they are for example located at the periphery, or in the centre of this surface). The lower and upper electrodes thus make it possible to inject an electric current into the device 1, in order to produce the luminous radiation in question.

This luminous radiation has an average wavelength λ (average wavelength of the emission spectrum of this emissive structure). This is its average wavelength in vacuum (or in a medium of index equal to 1).

When the emissive structure is formed of semiconductor materials having different optical indices, the average index n of the structure, mentioned above, corresponds to an average (for example, a volume average) of the optical indices of the parts of the emissive structure where the radiation is produced and of the parts through which this radiation passes. For the embodiment represented in FIG. 1, for example, the optical index n is an average of the respective optical indices of the lower layer 22, the upper layer 21, and the layers forming the planar quantum wells of the emissive part 23.

In practice, the average optical index n may be close (or even equal to) the optical index of the material that forms the upper layer 21.

The average optical index n, as well as the other optical indices mentioned herein, are indices at the average wavelength λ.

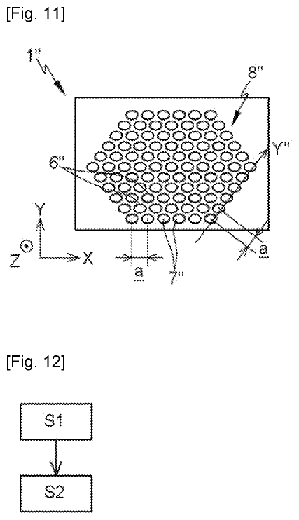

In the embodiment of FIG. 1, and in its alternatives of FIGS. 10 and 11, the optoelectronic device 1; 1′; 1″ is a light-emitting diode.

In this instance, it is a microLED, having micron transverse dimensions (which makes it possible to make display screens having a very high spatial resolution).

More precisely, the outlet surface 4 of the LED 1; 1′; 1″ occupies an area lower than 50 μm² (50 square microns), or even lower than 5 μm². The LED 1; 1′; 1″ may for example have a rectangular cross-section (cross-section along a plane parallel to the layers), the sides of this rectangle being each lower than 10, or even 3 or 2 microns.

As indicated above, the antireflective structure 3 of the device comprises a periodic sub-wavelength grating 8; 8′; 8″. This grating includes hollow parts 7; 7′; 7″ and protruding parts 6; 6′; 6″ forming a regular periodic structure, with a pitch a lower than λ/(2.n).

The protruding parts 6; 6′; 6″ protrude from the emissive structure 2 towards the outlet medium 5. Here, the outlet medium 5 extends into the hollow parts 7; 7′; 7″ of the grating, and fills these hollow parts. Alternatively, however, the hollow parts could be filled with a transparent material, having a different index than the outlet medium (the upper surface of the material in question then being planarised, to obtain a planar interface, flush with the top of the protruding parts, for example). In any case, the index of the material, or of the medium that fills the hollow parts, is denoted as nᵣ. When the outlet medium 5 extends into the hollow parts and fills them, as here, there is nᵣ=nₒᵤₜ (for example equal to nₐᵢᵣ).

The grating is formed by the periodic repetition of a given pattern, for example a hole 7′; 7″ or a groove 7 etched on the upper surface of the emissive structure 2, or a nano-column extending from the emissive structure to the outlet medium.

It will be noted that the grating 8; 8′; 8″ is devoid of metal parts: its protruding parts are formed by a semiconductor, or dielectric material (and the outlet medium, which occupies the hollow parts, is a dielectric medium).

The material, of which the protruding parts 6; 6′; 6″ of the grating are formed, has an optical index denoted as np.

The grating can be made by directly etching the upper surface, that is, the outlet surface of the emissive structure 2. The material (in practice a semiconductor material), of which the protruding parts 6; 6′; 6″ of the grating are formed, is then the same as for the upper layer 21 of the emissive structure (or the same as for the most superficial sub-layer of the upper layer, if this layer is formed of several sub-layers), and these protruding parts are as one piece with this upper layer (that is, without discontinuity of material). In this case, the optical index np of the protruding parts is the same as for this upper layer. It is then close, or even equal to, the average index n of the emissive structure. For the embodiment of FIG. 1, it can besides be considered that nₚ=n.

Making the grating in this way makes it possible, for the effective optical index of the grating, to conveniently obtain an intermediate value between the average index n of the emissive structure, and the index nₒᵤₜ of the outlet medium (since the protruding parts then have an index n, or close to n, while the hollow parts have an index nₒᵤₜ).

However, the grating could be made by depositing a layer of dielectric or semiconductor material on an upper face of the emissive structure, and then by etching the layer thus deposited. In this case, the material forming the protruding parts of the grating could be different from the material forming the most superficial layer of the emissive structure.

The grating 8 can be a one-dimensional grating, as in the case of the device 1 of FIG. 1 (also represented seen from above in FIG. 4). The hollow parts 7 are then rectilinear grooves parallel to each other. For this example, the grooves are grooves with a rectangular cross section (U-shaped groove).

The grating 8′; 8″ can also be a two-dimensional grating, including a pattern 7′; 7″ periodically repeated along a first direction X, with the pitch a, and also periodically repeated, along a second direction Y; Y″ different from the first direction.

FIG. 10 represents a first alternative, 1′, of the device of FIG. 1, seen from above. For this alternative, the grating 8′ is a two-dimensional grating, in this instance a rectangular grating, with a pitch a along the direction X and a pitch a′ along the direction Y, for which the repeated pattern is a cylindrical hole 7′.

FIG. 11 represents a second alternative, 1″, of the device of FIG. 1, seen from above. The grating 8″ is again a two-dimensional grating, in this instance a triangular grating, with a pitch a along the direction X and a pitch a along a direction Y″ (tilted at 60 degrees relative to the direction X). The repeated pattern is, again, a cylindrical hole 7″.

Other types of periodic two-dimensional gratings, for example with a hexagonal mesh, or corresponding to an Archimedean tiling could be utilised, as an alternative.

Given the very small dimensions of the grating pattern, a hole-type pattern will generally result in a more robust device than a nano-column-type pattern.

The depth of the grating 8; 8′; 8″ is denoted as D. It is the distance, measured along the direction Z, between the bottom of the hollow parts 7 and the top of the protruding parts 6.

The hollow parts 7 of the grating occupy a part of the total volume occupied by the grating, with a filling factor denoted as FF (sometimes called “air Filling Factor”). This filling factor is equal to the fraction of the total volume of the grating occupied by its hollow parts 7.

When the grating patterns have, as here, straight sides (perpendicular to the average plane defined by the outlet surface 4), this volume filling factor is equal to a surface filling factor, which is equal to the fraction of the total surface of the grating occupied by its hollow parts 7. In the case of the grating of FIG. 1, as the grating is one-dimensional, the filling factor FF is then expressed as w/a, where w is the width of the hollow parts 7.

As explained in the “summary” section, this grating, whose pitch a is lower than a λ/(2n), is not a diffractive grating, and, at least as a first approximation, its effect can be interpreted as that of a homogeneous effective medium 3_{eq}, whose index has an intermediate value between np (index of the material for the protruding parts) and nᵣ (index for the hollow parts).

The limit pitch below which there are no longer diffractive effects is λ/(2n), but the grating in question can have an even smaller pitch, for example lower than λ/(4n), or even λ/(8n) (modelling by a homogeneous effective medium will indeed be better the smaller the grating pitch).

For the one-dimensional grating of FIG. 1, it can be considered (as a first approximation) that the effective index of the layer formed by the grating is given:
by the following formula, in the case of a TE-type polarisation (“transverse electric” polarisation; polarisation—of the electric field—linear and parallel to the grating grooves):

n_{ARC,TE}={square root over ((FF.nᵣ⁻²+(1−FF).nₚ²)}
and by the following formula, in the case of a TM-type polarisation (“magnetic transverse” polarisation; linear polarisation and perpendicular to the grating grooves):

n_{ART,TM}={square root over ((FF.nᵣ⁻²+(1−FF).nₚ⁻²)⁻¹)}

The grating can therefore be dimensioned so that its effective index, n_{ARC,TE} or n_{ARC,TM} as the case may be, is equal to the index for which a homogeneous antireflective layer has the best performance, in terms of antireflective effect, that is, equal to \sqrt{n. nₒᵤₜ}.

When the emissive structure produces a luminous radiation, whose zo polarisation is substantially linear (which is generally the case for a quantum well LED as described above; the polarisation of the electric field being then generally parallel to the epitaxial layers), and when the grooves of the grating are parallel to this polarisation, the grating can then be dimensioned so that its filling factor FF is equal to the filling factor FF_{TE} given by the following formula F1:

\sqrt{FF_{TE}.nᵣ²+(1−FF_{TE}).nₚ²}=\sqrt{n. nₒᵤₜ} (F1)

And when the radiation produced has a substantially linear polarisation, perpendicular to the grating grooves, the grating can be dimensioned so that its filling factor FF is equal to the filling factor FF_{TM} given by the following formula F2:

{square root over ((FF_{TM}.nᵣ⁻²+(1−FF_{TM}).nₚ⁻²)⁻¹)}=\sqrt{n. nₒᵤₜ} (F2)

Herein, by equal, it is meant equal to better than within 20%, or even to within 10%. Besides, it will be noted that the formulas in question can be utilised to perform a pre-dimensioning, already very satisfactory, refined afterwards by performing numerical simulations to further increase performance of the device (in terms of luminous efficiency or angular aperture).

Moreover, a polarisation is considered to be substantially linear when the linearly polarised component of this radiation represents more than 80% of the luminous power.

As indicated above, for the embodiment of FIG. 1, there is nₚ=n and nᵣ=nₒᵤₜ, so that the formulas F1 and F2, which set the values of FF_{TM} and FF_{TE}, take the following form:

\sqrt{FF_{TE}.n²+(1−FF_{TE}).nₒᵤₜ²}=\sqrt{n. nₒᵤₜ}

and

{square root over ((FF_{TM}.n⁻²+(1−FF_{TM}).nₒᵤₜ⁻²)⁻¹)}=\sqrt{n. nₒᵤₜ.}

In the case of a two-dimensional grating, such as that of FIGS. 10 and 11, it can be considered that the effective index of the layer that the grating forms is the effective index n_{ARC,TE} mentioned above. Also, in this case, the grating can be dimensioned so that its filling factor FF is equal to the filling factor FF_{TE} mentioned above.

By analogy with a homogeneous antireflective layer, the depth D of the grating can, as here, be chosen equal to:
λ/(4 n_{ART,TE}), in the case of a two-dimensional grating, or a one-dimensional grating with TE-type polarisation, and
λ/(4 n_{ART,TM}), in the case of a one-dimensional grating with TM-type polarisation.

When the filling factor is adjusted as indicated above, such that the effective index of the grating (n_{ARC,TE} or n_{ART,TM} as the case may be) is equal to \sqrt{n. nₒᵤₜ}, then the depth D of the grating will be equal to λ/(4\sqrt{n. nₒᵤₜ}).

The numerical simulations set forth below show that the dimensioning criteria just set forth (for the filling factor FF, and for the thickness D), based on an analysis in terms of mean effective medium, actually result in a very effective antireflective effect. These numerical simulations also show that this type of grating modifies directivity of the radiation produced (which was however difficult to predict by an effective medium-type analysis, at least at first sight).

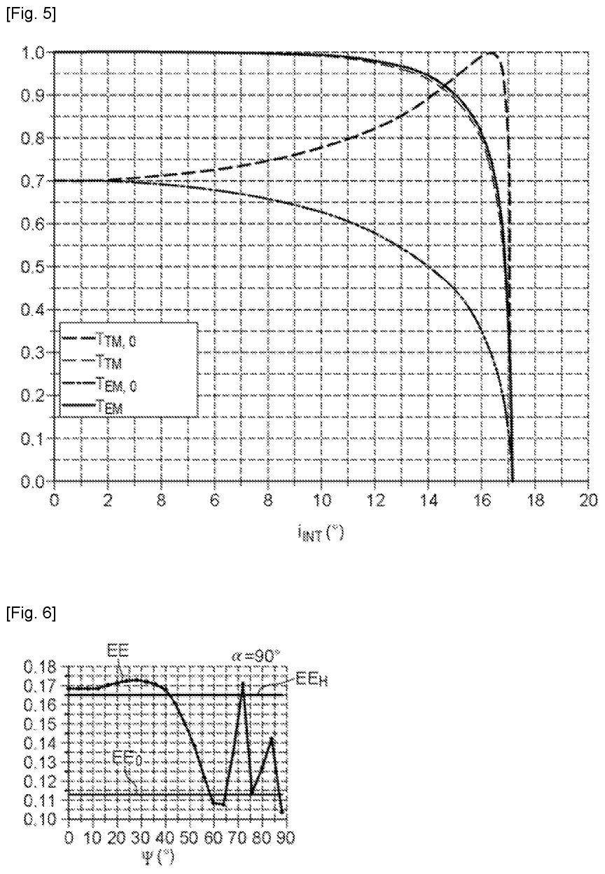

FIG. 5 shows transmission coefficients T_{TE} and T_{TM} (power transmission coefficients), calculated by numerical simulation (RCWA-type, for “rigorous coupled-wave analysis”), for the device of FIG. 1, with the following parameters: a=30 nm, λ=640 nm, n=nₚ=3.4 (index of the AlGaInP at the considered wavelength), nₒᵤₜ=nᵣ=1. The values of D and FF, determined according to the criteria indicated above, are then D=87 nm, FF=FF_{TE}=77% for the simulation performed with a TE-type polarised radiation, and FF=FF_{TM}=22% for the simulation performed with a TM-type radiation.

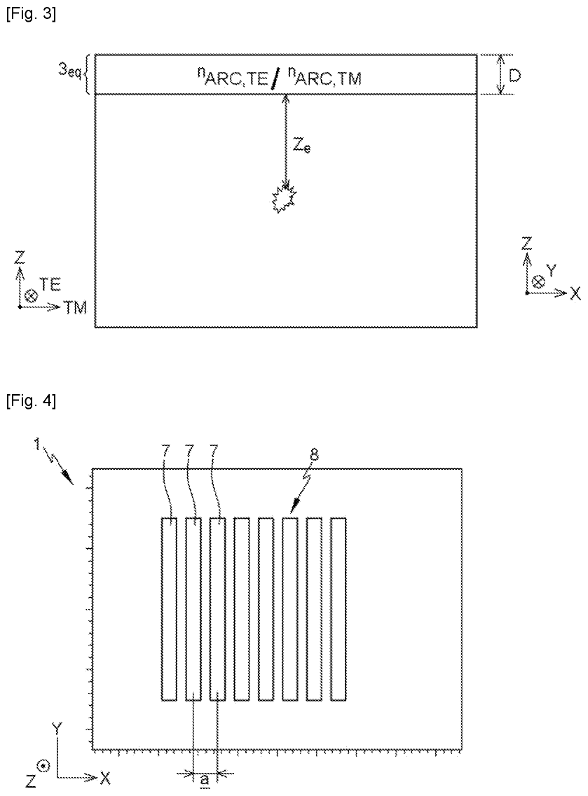

Moreover, for these simulations, it has been considered that the radiation was emitted, in the emissive structure, occasionally, at a depth Ze=500 nm under the outlet surface 4 (see FIGS. 2 and 3), and the emissive structure has been assimilated to a homogeneous medium of index n, semi-infinite (that is, occupying the entire half-space located under the grating).

In FIG. 5, the transmission coefficients T_{TE} and T_{TM} are represented as a function of the angle of incidence i_{INT} on the grating (angle formed with the axis Z), expressed in degrees. The angle of incidence i_{INT} is the angle of incidence on the inner side of the device, that is, the side of index n=3.4.

In this figure, the reflection coefficient T_{TE,O} and T_{TM,O}, corresponding to an emissive structure without any antireflective structure or layer (that is, for a bare interface between a medium of index n=3.4 and a medium of index n=1), is also represented. The coefficients T_{TE,O} and T_{TM,O} correspond respectively to a radiation having TE polarisation, and a radiation having TM-type polarisation.

The transmission coefficients in question are plotted for values of the angle of incidence between about 0 and 17 degrees, which is the limit value beyond which there is total internal reflection, for an interface n=3.4 /nₒᵤₜ=1.

As can be seen in this figure, the sub-length grating, dimensioned as indicated above, actually allows the glassy reflection at the interface between the emissive structure 2 and the outlet medium 5 to be almost fully cancelled out (since the coefficients T_{TE} and T_{TM} are almost equal to 1), and this almost up to the angle of incidence corresponding to the total internal reflection, both for a TE-type polarisation and for a TM-type polarisation (provided that the value of the filling factor FF is chosen adapted to the considered polarisation).

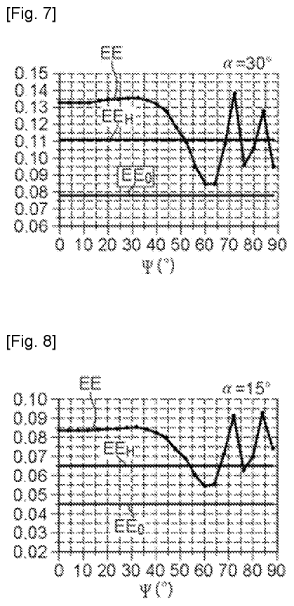

FIGS. 6, 7 and 8 in turn show the values of the extraction efficiency EE of the device of FIG. 1, for a TM-type polarisation (the results are comparable for a TE-type polarisation), for different values of the depth D of the grating. The extraction efficiency is equal to the ratio of:
on the one hand, the total power finally transmitted into the outlet medium, in a collection cone centred on the axis Z and of half angular aperture a (total angular aperture of 2α), to
on the other hand, the total power initially emitted, within the emissive structure 2.

FIGS. 6, 7 and 8 correspond respectively to the following values of angular aperture α of the collection cone: 90° (that is: integration over the entire half-space occupied by the outlet medium 5), 30° and 15°.

In each of these figures, the depth D of the grating is represented by the amount Ψ (rather than D), expressed in degrees, where D=λ/(4. n_{ARC,TM}.cos (Ψ)).

The results shown in these figures have been obtained by FDTD (“Finite-Difference Time-Domain”) numerical simulation, for the same parameters as in FIG. 5, except for the depth D of the grating which here varies.

In FIGS. 6 to 8, are also represented:
the extraction efficiency EE_{O} for a bare interface n=3.4/ₙₒᵤₜ=1, without any antireflective structure, respectively for the three values of the aperture angle (collection angle) α, and
the extraction efficiency EE_{H} obtained for a homogeneous antireflective layer, formed of a (theoretical) material whose uniform index is \sqrt{n. nₒᵤₜ}, and with a thickness equal to λ/(4\sqrt{n. nₒᵤₜ}).

In these figures, it is first noticed that a depth of the grating equal to λ/(4. n_{ARC,TM}) actually corresponds to the optimal (or near-optimal) depth in terms of extraction efficiency (this is the case of Ψ=0°, in the figures). It is also noticed that the sub-wavelength antireflective grating described here makes it possible to obtain an extraction efficiency as good as, and even better than, the ideal homogeneous medium mentioned above, and this for the three values of collection angle considered. The extraction efficiency of this grating is therefore very good, especially since the optimal condition n_{couche}=\sqrt{n. nₒᵤₜ} is generally not satisfied, for a real homogeneous antireflective layer (the choice of contemplatable materials being limited, in practice)

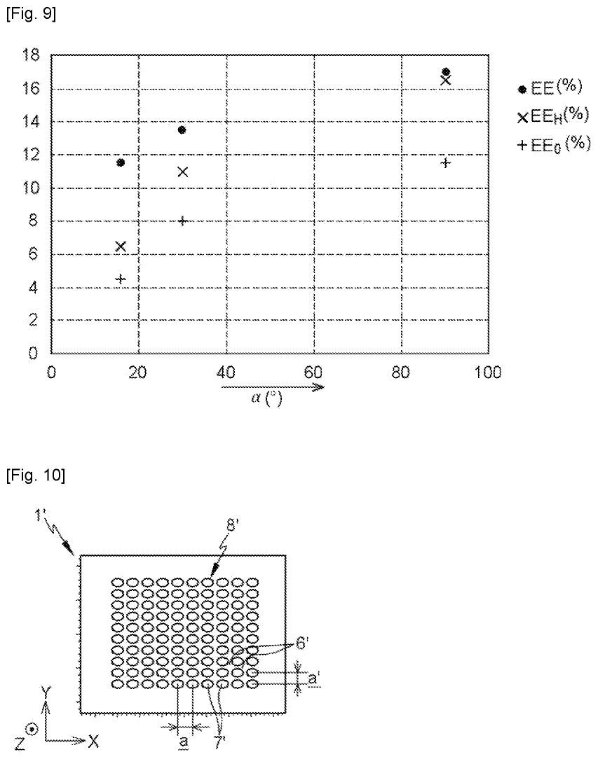

The extraction efficiency EE corresponding to D=λ/(4. n_{ARC,TM}), the extraction efficiency EE_{H}, and the extraction efficiency EE_{O} of the bare interface are plotted in FIG. 9 as a function of the angle a (expressed in degrees).

It can be noticed from this curve that, for α=90°, the extraction efficiency EE is equal to about 1.5 times EE_{O}, whereas for α=15°, it is equal to about 2.5 times EE_{O}, which clearly shows that the radiation finally emitted into the outlet medium is more directional (closer around the axis Z) with the grating in question than for a bare interface.

Similarly, for α=90°, the extraction efficiency EE is equal to about 1.03 times EE_{H}, while for α=15°, it is equal to about 1.8 times EE_{O}, which also shows that the radiation finally emitted into the outlet medium is more directional with the grating in question than with a homogeneous antireflective layer.

Besides, it is noticed that the ratio EE_{H}/EE_{O} is, on the contrary, substantially the same for α=90° and for α=15° (in this instance equal to about 1.4), the homogeneous antireflective layer not modifying a priori, or only slightly, the directivity of the emitted radiation, compared to a bare interface.

FIG. 12 schematically represents the steps S1 and S2 of a method for manufacturing an optoelectronic device such as that of FIG. 1.

The step S1 is a step of making an emissive structure 2, such as that described above, of which at least a part is formed of one or more semiconductor materials, configured to produce a luminous radiation when it is has an electric current flowing therethrough, said luminous radiation being produced within the emissive structure and having an average wavelength λ, the emissive structure having an average optical index n and being delimited by an outlet surface 4, through which at least a part of said luminous radiation exits. This step, performed according to known techniques, is not described in more detail.

As for step S2, it is a step of making an antireflective structure 3, such as described above, located at the outlet surface (4). During this step, a periodic sub-wavelength grating 8; 8′; 8″ is thus made, which includes hollow parts 7; 7′; 7″ and protruding parts 6; 6′; 6″ forming a regular periodic structure with a pitch a lower than λ/[2.n].

In this method, at the end of step S1, the emissive structure 2 has a planar upper face. And, in step S2, the grating 8 is made by electron lithography and then etching of this upper face. This etching step can typically be performed by reactive ion etching (RIE) or in a less standard way by focused ion beam (FIB).

It will be appreciated that the various embodiments described previously are combinable according to any technically permissible combinations.

1. An optoelectronic device comprising:
an emissive structure
at least a part of which is formed of one or more semiconductor materials,
configured to produce a luminous radiation when the emissive structure has an electric current flowing therethrough, said luminous radiation being produced within the emissive structure and having an average wavelength λ,
the emissive structure having an average optical index n and being delimited by an outlet surface, through which at least a part of said luminous radiation exits, and
an antireflective structure located at the outlet surface,
wherein the antireflective structure comprises a sub-wavelength periodic grating which includes hollow parts and protruding parts forming a regular periodic structure with a pitch (a) lower than λ/[2.n].

2. The device according to claim 1, wherein an area occupied by the outlet surface of the emissive structure is lower than 50 μm².

3. The device according to claim 2 wherein the area is lower than 5 μm².

4. The device according to claim 1, wherein the emissive structure includes a superficial upper layer, formed of a semiconductor material, and wherein the protruding parts of said grating, formed of the same semiconductor material as said superficial upper layer, are as one piece with the upper layer of the emissive structure.

5. The device according to claim 4, wherein:
the protruding parts of the grating are formed of a material having an optical index np,
a medium of optical index nous extends above the grating, opposite to the emissive structure,
a medium of index nᵣ fills the hollow parts of the grating, and wherein
a filling factor FF of the grating, equal to the fraction of the volume of the grating occupied by its hollow parts, is equal to the filling factor FF_{TE} given by the following formula F1: \sqrt{FF_{TE}. nᵣ²+(1−FF_{TE}). nₚ²}=\sqrt{n. nₒᵤₜ} (F1).

6. The device according to claim 1, wherein:
the protruding parts of the grating are formed of a material having an optical index nₚ,
a medium of optical index nₒᵤₜ extends above the grating, opposite to the emissive structure,
a medium of index nᵣ fills the hollow parts of the grating, and wherein
a filling factor FF of the grating, equal to the fraction of the volume of the grating occupied by its hollow parts, is equal to the filling factor FF_{TE} given by the following formula F1: \sqrt{FF_{TE}. nᵣ²+(1−FF_{TE}). nₚ²}=\sqrt{n. nₒᵤₜ} (F1).

7. The device according to claim 6, wherein the grating is one-dimensional, the hollow parts being rectilinear grooves parallel to each other, and wherein said radiation has a substantially rectilinear polarisation, and parallel to said grooves.

8. The device according to claim 6, wherein the grating is a two-dimensional grating including a pattern periodically repeated along a first direction, and also periodically repeated along a second direction different from the first direction.

9. The device according to claim 1, wherein,
the protruding parts of the grating are made of a material having an optical index nₚ,
a medium of optical index nₒᵤₜ extends above the grating, opposite to the emissive structure,
a medium of index nᵣ fills the hollow parts of the grating,
the grating is one-dimensional, the hollow parts being rectilinear grooves parallel to each other, and said radiation has a substantially rectilinear polarisation perpendicular to said grooves, and wherein
a filling factor FF of the grating, equal to the fraction of the volume of the grating occupied by its hollow parts, is equal to the filling factor FF_{TM} given by the following formula F2: {square root over ((FF_{TM}. nᵣ⁻²+(1−FF_{TM}). nₚ⁻²)⁻¹)}=\sqrt{n. nₒᵤₜ} (F2).

10. The device according to claim 1, wherein the grating has a depth D, along a direction perpendicular to the outlet surface, the depth D being equal to λ/(4\sqrt{n. nₒᵤₜ}), nₒᵤₜ being the optical index of the medium which extends above the grating, opposite to the emissive structure.

11. The device according to claim 1, the device being a light-emitting diode, wherein the emissive structure comprises:
a lower layer formed at least in part of a doped semiconductor,
an upper layer formed at least in part of a doped semiconductor, the lower and upper layers having opposite type doping, and
an emissive part which extends between the lower layer and the upper layer and which is capable of emitting said luminous radiation when it has an electric current flowing therethrough.

12. A display screen comprising an array of optoelectronic devices each in accordance with claim 1.

13. A method for manufacturing an optoelectronic device, comprising:
a step of making an emissive structure, at least a part of which is formed of one or more semiconductor materials, configured to produce a luminous radiation when it has an electric current flowing therethrough, said luminous radiation being produced within the emissive structure and having an average wavelength λ, the emissive structure having an average optical index n and being delimited by an outlet surface, through which at least a part of said luminous radiation exits, and
a step of making an antireflective structure, located at the outlet surface,
the method being characterised in that the step of making the antireflective structure comprises a step of making a sub-wavelength periodic grating which includes hollow parts and protruding parts forming a regular periodic structure with a pitch lower than λ/[2.n].

14. The method according to claim 13, wherein the emissive structure has, at the end of the step of making the emissive structure, a free upper face, and wherein the grating is made by electron lithography and then etching of said upper face.
